(19) United States
(12) Patent Application Publication
(10) Pub. No.: US 2022/0037204 A1
(43) Pub. Date: Feb. 3, 2022

(54) METHODS AND APPARATUS FOR FORMING STABILIZATION LAYERS

(71) Applicant: APPLIED MATERIALS, INC., Santa Clara, CA (US)

(72) Inventors: Wenjing XU, San Jose, CA (US); Gang SHEN, San Jose, CA (US); Feng CHEN, San Jose, CA (US); Tae Hong HA, San Jose, CA (US)

(21) Appl. No.: 16/983,402

(22) Filed: Aug. 3, 2020

(51) Int. Cl. H01L 21/768; H01L 23/532

(52) U.S. Cl. CPC H01L 21/76864; H01L 23/53266

(57) ABSTRACT

Methods and apparatus that forms a stabilization layer on copper-based material to inhibit formation of copper voids in the copper-based material. In some embodiments, a method of forming the stabilization layer on the copper-based material includes depositing a first stabilization layer on the copper-based material where the first stabilization layer forms a continuous film on the copper-based material and is formed of a first material that does not alloy with copper, depositing a second stabilization layer on the first stabilization layer where the second stabilization layer is formed from a second material that alloys with copper and where the first stabilization layer is configured to inhibit formation of voids in the copper-based material during subsequent high thermal budget processing.

### FIELD

Embodiments of the present principles generally relate to semiconductor processing of semiconductor substrates.

### BACKGROUND

During the formation of integrated circuits, multi-dimensional packaging may be used such as 3D packaging. In such cases, vertical and horizontal connections may be used to connect the integrated circuits found at different levels of the packaged circuit. Vias may be used which are essentially vertical conductors that pass through a substrate. Horizontal interconnects or trenches may be used to connect structures on one or more levels. Because copper has high electrical conductivity in 5 nm or less devices on the substrate, copper-based interconnects are typically used for most interconnects. Copper often migrates into surrounding materials and requires a barrier/liner layer to prevent the copper migration. Similarly, capping layers may be used to lop off the copper filled vias to prevent copper migration into subsequently deposited materials. The inventors have observed, however, that during subsequent processing of substrates with copper-based interconnects, the copper-based material would break down and prevent electrical current flow, creating performance issues.

Accordingly, the inventors have provided improved methods and apparatus for eliminating the breakdown of copper interconnects during, processing of a substrate.

### SUMMARY

Methods and apparatus for forming stabilization layers on copper-based materials are provided herein.

In some embodiments, a method of forming a stabilization layer on copper-based material may comprise depositing a first stabilization layer on the copper-based material, wherein the first stabilization layer forms a continuous film on the copper-based material and wherein the first stabilization layer is formed of a first material that does not alloy with copper, depositing a second stabilization layer on the first stabilization layer, wherein the second stabilization layer is formed from a second material that alloys with copper and wherein the first stabilization layer is configured to inhibit formation of voids in the copper-based material during subsequent high thermal budget processing.

In some embodiments, the method may further include wherein the first material is tungsten or molybdenum and the second material is cobalt, wherein the first material is ruthenium with a thickness of at least approximately 5 angstroms and the second material is cobalt with a thickness greater than approximately 25 angstroms, wherein the copper-based material includes copper oxide, depositing the first stabilization layer using a physical vapor deposition (PVC)) process or a chemical vapor deposition (CVD) process and depositing the second stabilization layer using a PVD process or a CVD process, depositing the first stabilization layer using an oxygen-based precursor or an oxygen-free precursor and depositing the second stabilization layer using an oxygen-based precursor or an oxygen-free precursor, exposing the copper-based material to oxygen prior to deposition of the first stabilization layer, depositing the first stabilization layer using a selective deposition process and depositing the second stabilization layer using a selective deposition process, depositing the first stabilization layer and the second stabilization layer at a temperature of approximately 100 degrees Celsius to approximately 300 degrees Celsius, depositing the first stabilization layer and the second stabilization layer at a pressure of approximately 3 Torr to approximately 25 Torr, and/or wherein the subsequent high thermal budget is approximately 400 degrees Celsius or higher.

In some embodiments, a method of forming a capping layer on copper-based material may comprise depositing a first capping layer on the copper-based material, wherein the first capping layer forms a continuous film on the copper-based material and wherein the first capping layer is formed of a first material that does not alloy with copper, depositing a second capping layer on the first capping layer, wherein the second capping layer is formed from a second material that alloys with copper and wherein the first capping layer is configured to inhibit formation of voids in the copper-based material during subsequent high thermal budget processing.

In some embodiments, the method may further include wherein the first material is tungsten or molybdenum and the second material is cobalt, wherein the first material is ruthenium with a thickness of at least approximately 5 angstroms and the second material is cobalt with a thickness greater than approximately 25 angstroms, wherein the copper-based material includes copper oxide, depositing the first capping layer using an oxygen-based precursor or an oxygen-free precursor and depositing the second capping layer using an oxygen-based precursor or an oxygen-free precursor, exposing the copper-based material to oxygen prior to deposition of the first capping layer, and/or wherein the subsequent high thermal budget processing includes a temperature of approximately 400 degrees Celsius or higher.

In some embodiments, a non-transitory, computer readable medium having instructions stored thereon that, when executed, cause a method for forming a stabilization layer on copper-based material to be performed, the method may comprise depositing a first stabilization layer on the copper-based material, wherein the first stabilization layer forms a continuous film on the copper-based material and wherein the first stabilization layer is formed of a first material that does not alloy with copper, depositing a second stabilization layer on the first stabilization layer, wherein the second stabilization layer is formed from a second material that alloys with copper and wherein the first stabilization layer is configured to inhibit formation of voids in the copper-based material during subsequent high thermal budget processing.

In some embodiments, the method may further include wherein the subsequent high thermal budget processing includes a temperature of approximately 400 degrees Celsius or higher, wherein the first stabilization layer or the second stabilization layer is deposited using an oxygen-based precursor or an oxygen-free precursor, and/or wherein the first material is formed from ruthenium, tungsten, or molybdenum.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a method of forming a stabilization layer on copper-based material in accordance with some embodiments of the present principles.

FIG. 2 depicts a cross-sectional view of a stabilization layer on copper-based material in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods and apparatus provide stabilization layers on copper-based materials that prevent corrosion and voids in the copper-based materials during substrate processing. In the development of advanced nodes, thermal stresses on devices increases substantially. Under aggressive thermal budgets, the reliability of the devices is severely degraded due to the formation of copper line corrosion or breakage by current manufacturing techniques for liners and cappings. The present methods and apparatus beneficially overcome defects in the copper, producing high quality interconnects without current flow issues developing during subsequent heating processes. An additional benefit is that the stabilization layer uses combinations of existing processes rather than creating a new process, saving production costs. Another advantage of the methods and apparatus of the present principles is that the copper may be exposed to oxygen during processing without any degradation in performance, Standalone chemical mechanical polishing (CMP) processes may be performed on the copper (e.g., a vacuum break—exposing the copper to air in non-integrated tool sets) during the process without any drawbacks. In addition, the techniques of the present principles work on sidewall surfaces, bottom surfaces, and on top surfaces and the like.

The inventors have discovered that cobalt, which is used due to cobalt's high selectivity and adhesion qualities with copper, causes copper corrosion and copper voids to occur during subsequent heating of the substrate. The inventors have found that by using a binary stabilization layer over the copper, the formation of voids and corrosion in the copper during subsequent heating processes is eliminated. The binary stabilization layer uses a combination of materials with different interactions with copper, with an underlying layer that does not alloy with, copper.

In back end of line (BEOL) processes, a copper line at a via bottom is exposed to air and oxidizes to form copper oxide during etching processes. Before deposition of a liner, the copper oxide is reduced to copper by a preclean process. Likewise, a copper interconnect line is oxidized during a CMP process. Before a capping deposition, the copper oxide is reduced to copper by a preclean process. In both cases, the copper undergoes volume shrinkage when the copper oxide is reduced to copper, leading to micro-voids forming in the copper. The inventors have found that when the copper is subsequently heated during processing, the copper flows and condenses, causing the micro-voids to join together and form larger voids in the copper. The large voids reduce the performance of the copper interconnects and may even be large enough to break the copper interconnect and disrupt the current carrying capabilities of the copper interconnect, making a semiconductor device inoperable. In addition, when copper is deposited with a physical vapor deposition (PVD) process, defects and grain boundaries occur in the deposited copper crystal. The inventors have found that when the copper is subsequently heated during processing, the copper experiences grain growth and the total volume of the copper decreases, causing copper corrosion and/or copper voids in the copper interconnect.

The inventors have found that materials that have a strong inter-diffusion with copper under a high thermal budget relieve the internal surface tensions around micro-voids and/or defects in the copper when diffusion occurs. When the copper is heated during subsequent processing, the micro-voids more easily fuse together and form very large voids and/or breakage within the copper interconnect. By having a binary stabilization layer with a top layer of a first material that may alloy with copper and an underlying layer of a second material that does not alloy with copper, the formation of corrosion and/or voids within the copper during subsequent heating is eliminated, enhancing the performance of the copper interconnect. The combination of materials in the binary stabilization layer prevents voids and/or corrosion even if the first material and the second material, if used alone, would cause corrosion to the copper.

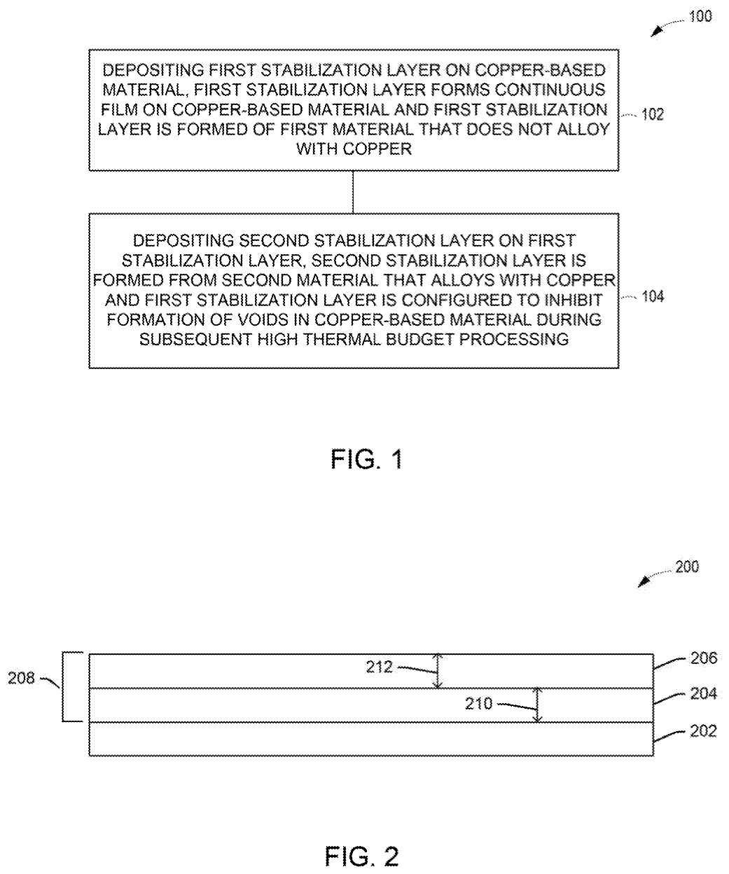

FIG. 1 is a method 100 of forming a binary stabilization layer 208 on copper-based material 202 in accordance with some embodiments. The method 100 is described in conjunction with FIG. 2 which depicts a cross-sectional view 200 of the binary stabilization layer 208 in accordance with some embodiments. In block 102, a first stabilization layer 204 is deposited on a copper-based material 202. The copper-based material 202 may be, but is not limited to, copper, copper-oxide, and/or copper alloys and the like. The first stabilization layer 204 may be deposited by a PVD process or a CVD process and the like. The first stabilization layer 204 may be deposited using an oxygen-based precursor or an oxygen-free precursor. The method 100 works on copper or copper-oxide. The copper-based material 202 may also be exposed to oxygen (e.g., vacuum break between processes) prior to the deposition of the first stabilization layer 204 without a decrease in effectiveness of the method 100 and without requiring a 100% in-situ process with no vacuum breaks. In some embodiments, the first stabilization layer 204 may be deposited using a selective deposition process. Pre-cursors used in deposition of the first stabilization layer 204 may have different ligands without affecting the process.

The first stabilization layer 204 is deposited such that the first stabilization layer 204 forms a continuous film on the copper-based material 202. In some embodiments, a thickness 210 of the first stabilization layer 204 may be approximately 5 angstroms or more. In some embodiments, the thickness 210 of the first stabilization layer 204 may be greater than zero, to less than approximately 4 angstroms. The first stabilization layer 204 is formed of a first material that does not alloy with copper. In some embodiments, the first material may be ruthenium and the thickness of the first stabilization layer may be approximately 5 angstroms or more. In some embodiments, the first material may be tungsten or molybdenum.

In block 104, a second stabilization layer 206 is deposited on the first stabilization layer, forming the binary stabilization layer 208. In some embodiments, the binary stabilization layer 208 may be a liner layer. In some embodiments, the binary stabilization layer 208 may be a capping layer. The second stabilization layer 206 may be deposited by a PVD process or a CVD process and the like. The second stabilization layer 206 may be deposited using an oxygen-based precursor or an oxygen-free precursor. Pre-cursors used in deposition of the second stabilization layer 206 may have different ligands without affecting the process. In some embodiments, the second stabilization layer 206 may be deposited using a selective deposition process. In some embodiments, the second stabilization layer 206 has a thickness 212 greater than zero to approximately 40 angstroms or more. In some embodiments, the second stabilization layer 206 has a thickness 212 greater than approximately 25 angstroms when used with a first material formed from ruthenium.

The second stabilization layer 206 is formed of a second material that may allow with copper. In some embodiments, the second material may be cobalt and the like. The first stabilization layer 204 is configured to inhibit formation of voids and/or corrosion in, the copper-based material 202 during subsequent high thermal budget, processing. The first stabilization layer 204 resists intermetal diffusion of the second stabilization layer 206 into the copper-based material 202 when undergoing a subsequent high thermal budget process. The thickness 210 of the first stabilization layer 204 is sufficient to resist the intermetal diffusion to a level that prevents corrosion and/or voids in the copper-based material 202. The non-alloying with copper characteristics of the first material and the alloying tendencies with copper of the second material facilitate in determining the effectiveness and thickness of the first stabilization layer 204 to inhibit corrosion and/or void formation in the copper-based material 202.

In some embodiments, a subsequent high thermal budget is approximately 400 degrees Celsius or higher. In some embodiments, the first stabilization layer 204 and/or the second stabilization layer 206 may be deposited at a temperature of approximately 100 degrees Celsius to approximately 300 degrees Celsius. In some embodiments, the first stabilization layer 204 and/or the second stabilization layer 206 may be deposited at a temperature of approximately 100 degrees Celsius to approximately 250 degrees Celsius. In some embodiments, the first stabilization layer 204 and the second stabilization layer 206 may be deposited at a pressure of approximately 3 Torr to approximately 25 Torr.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method of forming a stabilization layer on copper-based material, comprising:
depositing a first stabilization layer on the copper-based material, wherein the first stabilization layer forms a continuous film on the copper-based material and wherein the first stabilization layer is formed of a first material that does not alloy with copper;
depositing a second stabilization layer on the first stabilization layer, wherein the second stabilization layer is formed from a second material that alloys with copper; and
wherein the first stabilization layer is configured to inhibit formation of voids in the copper-based material during subsequent high thermal budget processing.

2. The method of claim 1, wherein the first material is tungsten or molybdenum and the second material is cobalt.

3. The method of claim 1 whereat the first material is ruthenium with a thickness of at least approximately 5 angstroms and the second material is cobalt with a thickness greater than approximately 25 angstroms.

4. The method of claim 1, wherein the copper-based material includes copper oxide.

5. The method of claim 1, further comprising:
depositing the first stabilization layer using a physical vapor deposition (PVD) process or a chemical vapor deposition (CVD) process; and
depositing the second stabilization layer using a PVD process CVD process.

6. The method of claim 1, further comprising:
depositing the first stabilization layer using n oxygen-based precursor or an oxygen-free precursor; and
depositing the second stabilization layer using an oxygen-based precursor or an oxygen-free precursor.

7. The method of claim 1, further comprising:
exposing the copper-based material to oxygen prior to deposition of the first stabilization layer.

8. The method of claim 1, further comprising:
depositing the first stabilization layer using a selective depositions process; and
depositing the second stabilization layer using a selective deposition process.

9. The method of claim 1, further comprising:
depositing the first stabilization layer and the second stabilization layer at a temperature of approximately 100 degrees Celsius to approximately 300 degrees Celsius.

10. The method of claim 1, further comprising:
depositing the first stabilization layer and the second stabilization layer at a pressure of approximately 3 Torr to approximately 25 Torr.

11. The method of claim 1, wherein the subsequent high thermal budget is approximately 400 degrees Celsius or higher.

12. A method of forming a capping layer on copper-based material, comprising:
depositing a first capping layer on the copper-based material, wherein the first capping layer forms a continuous film on the copper-based material and wherein the first capping layer is formed of a first material that does not alloy with copper;
depositing a second capping layer on the first capping layer, wherein the second capping layer is formed from a second material that alloys with copper; and
wherein the first capping layer is configured to inhibit formation of voids in the copper-based material during subsequent high thermal budget processing.

13. The method of claim 12, wherein the first material is tungsten or molybdenum and the second material is cobalt.

14. The method of claim 12, wherein the first material is ruthenium with a thickness of at least approximately 5 angstroms and the second material is cobalt with a thickness greater than approximately 25 angstroms.

15. The method of claim 12, wherein the copper-based material includes copper oxide.

16. The method of claim 12, further comprising:
depositing the first capping layer using an oxygen-based precursor or an oxygen-free precursor; and
depositing the second capping layer using an oxygen-based precursor or an oxygen-free precursor.

17. The method of claim 12, further comprising:
exposing the copper-based material to oxygen prior to deposition of the first capping layer.

18. The method of claim 12, wherein the subsequent high thermal budget processing includes a temperature of approximately 400 degrees Celsius or higher.

19. A non-transitory, computer readable medium having instructions stored thereon that, when executed, cause a method for forming a stabilization layer on copper-based material to be performed, the method comprising:
depositing a first stabilization layer on the copper-based material, wherein the first stabilization layer forms a continuous film on the copper-based material and wherein the first stabilization layer is formed of a first material that does not alloy with copper;
depositing a second stabilization layer on the first stabilization layer, wherein the second stabilization layer is formed from a second material that alloys with copper; and
wherein the first stabilization layer is configured to inhibit formation of voids in the copper-based material during subsequent high thermal budget processing.

20. The non-transitory, computer readable medium of claim 19, wherein the subsequent high thermal budget processing includes a temperature of approximately 400 degrees Celsius or higher, wherein the first stabilization layer or the second stabilization layer is deposited using an oxygen-based precursor or an oxygen-free precursor, or wherein the first material is formed from ruthenium, tungsten, or molybdenum.
